(19) United States
(12) Patent Application Publication
(10) Pub. No.: US 2025/0251764 A1
(43) Pub. Date: Aug. 7, 2025

(54) COOLING CASE FOR ELECTRONIC DEVICE

(71) Applicant: Joseph Leo Wesley, Pismo Beach, CA (US)

(72) Inventor: Joseph Leo Wesley, Pismo Beach, CA (US)

(21) Appl. No.: 18/431,212

(22) Filed: Feb. 2, 2024

(51) Int. Cl. G06F 1/20; G03B 17/56; G06F 1/16; H05K 7/20

(52) U.S. Cl. CPC G06F 1/203; G06F 1/1607; H05K 7/20172; G03B 17/566

(57) ABSTRACT

An embodiment of the present invention is a case for an electronic device, comprising: a case frame for holding an electronic device; an internal fan directing air across the back of the electronic device; and an internal rechargeable battery for powering the internal fan.

### BACKGROUND

An overheated tablet or smartphone usually runs slower, drains the battery fast, shortens its life span, or even can explode or catch on fire. Cooling cases to reduce these risks have been described in the prior art patent literature.

For example, U.S. Pat. No. 9,608,686 discloses a case for cooling a portable electronic device, the case including a housing and a cartridge. The housing holds the electronic device and has a cartridge compartment for retaining the cartridge. The cartridge includes sets of compartments for retaining substances configured to generate an endothermic reaction when mixed or combined. Pairs of compartments are separated by a divider configured to be selectively breached. The duration of the cooling effect may be extended by periodically breaching dividers of additional compartment pairs. The magnitude of the cooling effect may be increased by breaching multiple compartment pairs at once. The case may also include electronic components for monitoring the temperature of the electronic device and automatically initiating an endothermic reaction when the temperature reaches a predetermined threshold.

US20210242890 discloses a protective and cooling case for an electronic device able to reduce the temperature of the electronic device while protecting said electronic device. The protective and cooling case includes a case body, a securing mechanism, and at least one cooling module. The case body is a structure that is wrapped around the electronic device in order to protect the electronic device from shock forces when or if accidentally dropped. The case body can be any shape and size to protect various types of electronic devices such as, but not limited to, mobile phones or electronic tablets. The securing mechanism is a means to securely attach the at least one cooling module to the case body. The at least one cooling module is used to reduce the temperature of the electronic device.

However, prior art cooling cases are lacking in durability, flexibility for operation in varied environments and suitability for critical applications like aviation.

### SUMMARY OF INVENTION

Therefore, the present invention provides a case for an electronic device with a cooling fan also containing an internal battery for recharging the electronic device. An embodiment of the present invention is made of carbon impregnated plastic as well as carbon fiber for strength and impact as well as fire resistance.

According to an aspect of the present invention, there is provided a case for an electronic device, comprising: a case frame for holding an electronic device; an internal fan directing air across the back of the electronic device; and an internal rechargeable battery for powering the internal fan.

### BRIEF DESCRIPTION OF THE DRAWINGS

FIG. 1 illustrates a top view of the electronic device cooling case according to the present invention.

FIG. 2 illustrates a perspective view of the electronic device cooling case according to the present invention.

FIG. 3 illustrates the components of the electronic device cooling case according to the present invention.

### DETAILED DESCRIPTION

Although optimized for use in aviation and compatible with various mounting systems in the aviation and drone industries, the present invention also is highly useful in other industries where protection, cooling, and powering of electronic devices is mission-critical.

The present invention promotes safety by greatly reducing EFB/iPad/tablet overheating to and offering impact protection iPad/EFB/tablets.

The present invention also provides battery backup to USB power devices. A preferred embodiment of the present invention has an internal rechargeable battery.

The present invention offers cockpit mounting capability for propellor and jet aircraft pilots and transmitter mounting capabilities for drone pilots. The present invention is compatible with MyGoFlight's Sport Mount System by using the MNT-1665 Sport Camera Adapter. It is also compatible with RAM mounting systems, X-Grip Mount. It is compatible with all MAVMOUNT Controller Adapters as well as other systems available for drones.

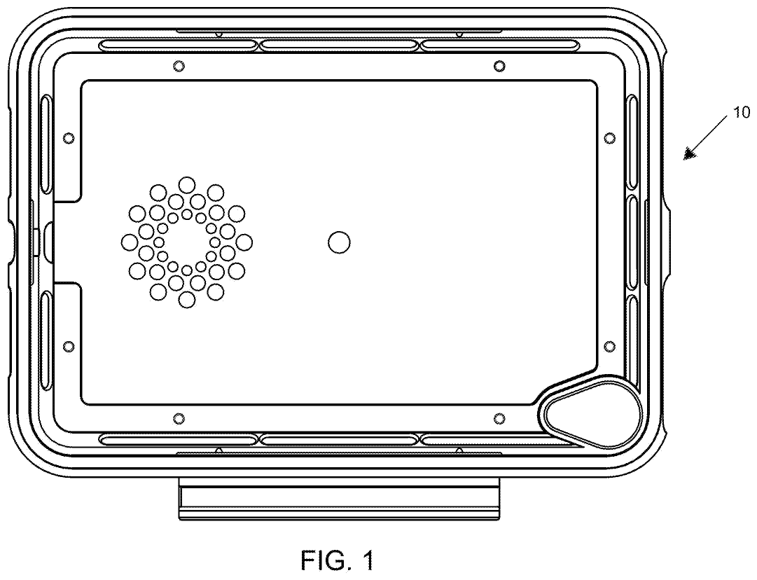

FIG. 1 illustrates a top view of the electronic device cooling case according to the present invention.

Case 10 draws cool air in through an internal fan and directs it across the back of the electronic device, keeping it from overheating. Efficient cooling is provided by having the cooling capability utilized when needed by pushing the on/off button on the back side of the case.

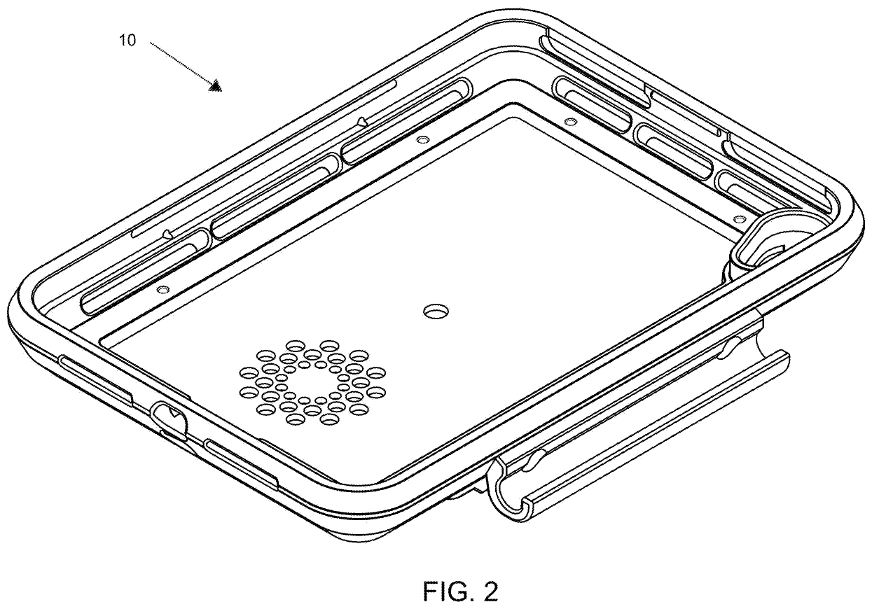

FIG. 2 illustrates a perspective view of the electronic device cooling case according to the present invention.

Power cables are not needed for case 10. A high-capacity internal rechargeable battery powers the cooling feature. This internal battery can also charge USB devices such as mobile phones and other common USB-powered products by simply plugging the device into the provided USB-C input port.

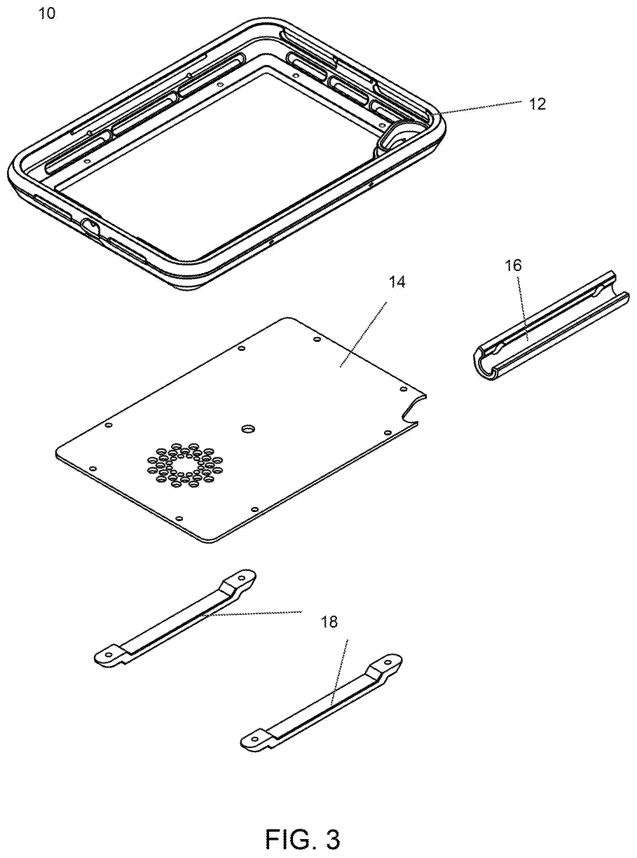

FIG. 3 illustrates the components of the electronic device cooling case according to the present invention.

Case 10 is comprised of the components illustrated in FIG. 3. Side frame 12 connects to back plate 14. Pen holder 16 is provided attachable to side frame 12.

Mounting brackets 18 can be used to mount case 10 on a variety of mounting systems.

The illustrations of embodiments described herein are intended to provide a general understanding of the structure of various embodiments, and they are not intended to serve as a complete description of all the elements and features of apparatus and systems that might make use of the structures described herein.

Specifically, fan location can vary, battery capacity can vary, air induction location can vary, and air exhaust locations can vary.

Many other embodiments will be apparent to those of skill in the art upon reviewing the above description. Other embodiments may be utilized and derived therefrom, such that structural and logical substitutions and changes may be made without departing from the scope of this disclosure.

Figures are also merely representational and may not be drawn to scale. Certain proportions thereof may be exaggerated, while others may be minimized. Accordingly, the specification and drawings are to be regarded in an illustrative rather than a restrictive sense. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description. Therefore, it is intended that the disclosure not be limited to the particular embodiment(s) disclosed.

What is claimed is:

1. A case for an electronic device, comprising:
a case frame for holding an electronic device;
an internal fan directing air across the back of the electronic device; and
an internal rechargeable case battery for powering the internal fan.

2. The case for an electronic device of claim 1, further comprising one or more USB-C input ports for charging an electronic device using the internal rechargeable case battery.

3. The case for an electronic device of claim 1, wherein the case frame comprises carbon impregnated plastic.

4. The case for an electronic device of claim 1, wherein the case frame comprises carbon fiber.

5. The case for an electronic device of claim 1, further comprising a mounting bracket.

6. The case for an electronic device of claim 5, wherein the mounting bracket is compatible with X-Grip Mount.

7. The case for an electronic device of claim 5, wherein the mounting bracket is compatible with MNT-1665 Sport Camera Adapter.

8. The case for an electronic device of claim 5, wherein the mounting bracket is compatible with MAVMOUNT Controller Adapters.

9. The case for an electronic device of claim 1, further comprising an attached pen holder.

10. The case for an electronic device of claim 1, further comprising an on/off switch for the internal fan.
